(19) United States
(12) Patent Application Publication
(10) Pub. No.: US 2018/0010238 A1
(43) Pub. Date: Jan. 11, 2018

(54) FILM-FORMING APPARATUS AND FILM-FORMING METHOD

(71) Applicant: Japan Display Inc., Tokyo (JP)

(72) Inventor: Kengo KATO, Tokyo (JP)

(21) Appl. No.: 15/494,580

(22) Filed: Apr. 24, 2017

(30) Foreign Application Priority Data
Jul. 8, 2016 (JP) 2016-135675

(51) Int. Cl. C23C 14/24; C23C 14/58; H01L 21/02; H01L 27/12

(52) U.S. Cl. CPC C23C 14/243; H01L 27/1266; H01L 27/1248; C23C 14/58; H01L 21/0217; H01L 27/124

(57) ABSTRACT

A film-forming apparatus is provided. The film-forming apparatus includes: a head connected to an evaporation source and having a plurality of opening portions; and a heater wound around the head. The heater has a first region at a side of the evaporation source and a second region at an opposite side of the first region from the evaporation source. The heater is arranged ununiformly in comparison between the first region and the second region. Furthermore, a film-forming method by using this film-forming apparatus is provided.

### CROSS REFERENCE TO RELATED APPLICATIONS

This application is based on and claims the benefit of priority from the prior Japanese Patent Application No. 2016-135675, filed on Jul. 8, 2016, the entire contents of which are incorporated herein by reference.

### FIELD

An embodiment of the present invention relates to an apparatus and a method for forming a film including an organic compound or an inorganic compound.

### BACKGROUND

A technology for forming a thin film of an organic compound or an inorganic compound, e.g., a technology for forming a thin film with a thickness ranging from approximately several angstroms to several hundred micrometers, is an extremely important technology when a semiconductor device is manufactured. Such a thin film can be prepared with a variety of methods, and a vapor-phase method is represented as a typical example. The vapor-phase method is roughly classified into a physical method (physical vapor deposition) and a chemical method (chemical vapor deposition).

A vacuum evaporation method (hereinafter, simply referred to as an evaporation method or evaporative deposition) has been known as one of the simplest methods among the physical methods. This is a method to obtain a thin film in which a material is heated with a resistive heating method at an evaporation source under a high vacuum to vaporize the material, a substrate is exposed to the obtained vapor to solidify the vaporized material, and then the solidified material is deposited. In order to prevent a vaporized material with a low vapor pressure or a high melting point from solidifying before reaching a substrate, Japanese patent application publications No. 2012-219376, No. 2008-291339, and No. 2012-248486 disclose an increase in efficiency of evaporative deposition by providing a heater for heating a periphery of an ejection port of a material in addition to a heater for heating a vessel such as a crucible filled with the material.

### SUMMARY

An embodiment of the present invention is a film-forming apparatus including: an evaporation source; a head connected to the evaporation source and comprising a plurality of opening portions; and a heater wound around the head. The heater has a first region at a side of the evaporation source and a second region at an opposite side of the first region from the evaporation source in the first region. The heater is located in the first region is arranged in a first arrangement state, and the heater located in the second region is arranged in a second arrangement state different from the first arrangement state.

An embodiment of the present invention is a film-forming method including: a step of heating a material at an evaporation source and vaporizing the material; a step of supplying vapor of the material into a head connected to the evaporation source and comprising a plurality of opening portions; a step of ejecting the vapor from the head through the plurality of opening portions; and a step of heating the head with a heater wound around the head during the heating of the material. The heater has a first region at a side of the evaporation source, and a second region at an opposite side of the first region from the evaporation source. The heater is located in the first region is arranged in a first arrangement state, and the heater located in the second region is arranged in a second arrangement state different from the first arrangement state.

### BRIEF DESCRIPTION OF DRAWINGS

FIG. 1 is a schematic side view of a film-forming apparatus according to an embodiment of the present invention;

FIG. 2 is a schematic top view of a film-forming apparatus according to an embodiment of the present invention;

FIG. 3 is a schematic top view of a film-forming apparatus according to an embodiment of the present invention;

FIG. 4 is a schematic cross-sectional view of a film-forming apparatus according to an embodiment of the present invention;

FIG. 5 is a schematic side view of a film-forming apparatus according to an embodiment of the present invention;

FIG. 6 is a schematic cross-sectional view of a film-forming apparatus according to an embodiment of the present invention;

FIG. 7A and FIG. 7B are schematic cross-sectional views of a film-forming apparatus according to an embodiment of the present invention;

FIG. 8 is a schematic cross-sectional view of a film-forming apparatus according to an embodiment of the present invention;

FIG. 9A and FIG. 9B are respectively a schematic side view and cross-sectional view of a film-forming apparatus according to an embodiment of the present invention;

FIG. 10A is a schematic top view of a sheet-shaped heater of a film-forming apparatus according to an embodiment of the present invention, and FIG. 10B is a schematic cross-sectional view of the film-forming apparatus;

FIG. 11 is a schematic top view of a sheet-shaped heater of a film-forming apparatus according to an embodiment of the present invention;

FIG. 12 is a schematic side view of a film-forming apparatus according to an embodiment of the present invention;

FIG. 13A is a schematic top view of a sheet-shaped heater of a film-forming apparatus according to an embodiment of the present invention, and FIG. 13B and FIG. 13C are a schematic side view and cross-sectional view of the film-forming apparatus, respectively;

FIG. 14 is a schematic top view of a sheet-shaped heater of a film-forming apparatus according to an embodiment of the present invention;

FIG. 15 is a schematic side view of a film-forming apparatus according to an embodiment of the present invention;

FIG. 16 is a schematic side view of a film-forming apparatus according to an embodiment of the present invention;

FIG. 17 is a schematic top view of a film-forming apparatus according to an embodiment of the present invention;

FIG. 18 is a schematic cross-sectional view of a substrate used in a film-forming method according to an embodiment of the present invention;

FIG. 19 is a schematic cross-sectional view for explaining a film-forming method according to an embodiment of the present invention;

FIG. 20 is a schematic cross-sectional view for explaining a film-forming method according to an embodiment of the present invention;

FIG. 21 is a schematic cross-sectional view for explaining a film-forming method according to an embodiment of the present invention;

FIG. 22 is a schematic cross-sectional view for explaining a film-forming method according to an embodiment of the present invention;

FIG. 23 is a schematic cross-sectional view for explaining a film-forming method according to an embodiment of the present invention; and

FIG. 24 is a schematic cross-sectional view for explaining a film-forming method according to an embodiment of the present invention;

### DESCRIPTION OF EMBODIMENTS

Hereinafter, the embodiments of the present invention are explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, they are only an example, and do not limit the interpretation of the invention. In the specification and the drawings, the same reference number is provided to an element that is the same as that which appears in preceding drawings, and a detailed explanation may be omitted as appropriate.

In the specification and the scope of the claims, unless specifically stated, when a state is expressed where a structure is arranged “over” another structure, such an expression includes both a case where the substrate is arranged immediately above the “other structure” so as to be in contact with the “other structure” and a case where the structure is arranged over the “other structure” with an additional structure therebetween.

### First Embodiment

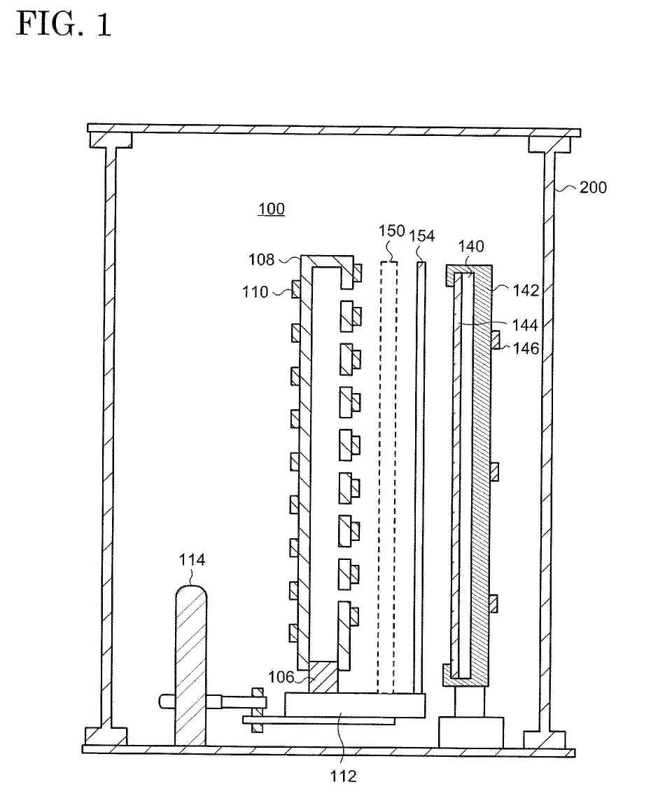

In the present embodiment, a structure of a film-forming apparatus 100 and a film-forming method using the film-forming apparatus 100 according to an embodiment of the present invention are explained by using FIG. 1 to FIG. 15. The film-forming apparatus 100 is an apparatus for forming a film over a substrate 140 by evaporative deposition and is also called an evaporation apparatus.

### 1. Outline Structure

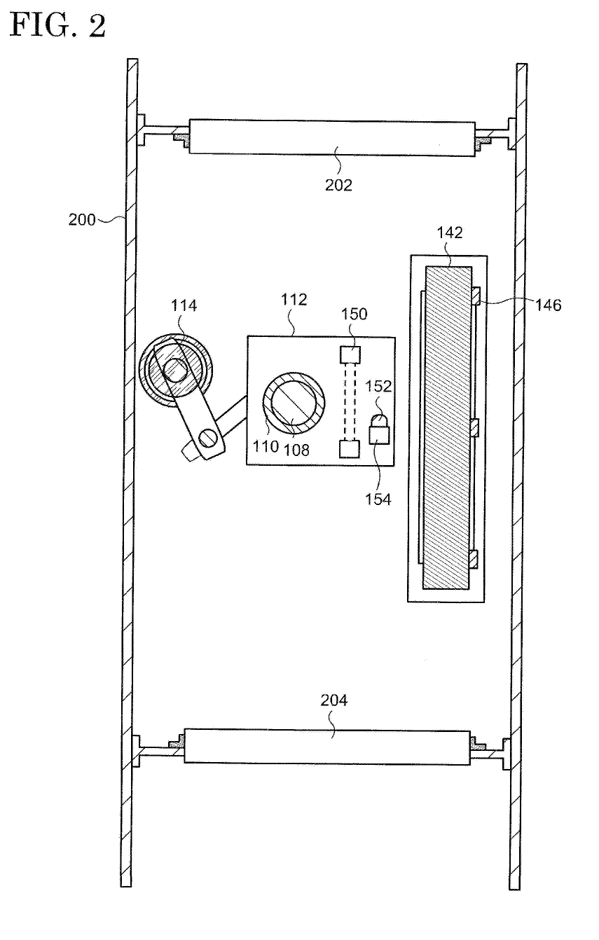

A schematic side view and top view of the film-forming apparatus 100 and a chamber 200 installable with the film-forming apparatus 100 are shown in FIG. 1 and FIG. 2, respectively. As shown in FIG. 1, the film-forming apparatus 100 includes: an evaporation source 106 containing a vessel 104 for holding a crucible 102 described later; and a closed tube 108. Here, a closed tube means a tube having one closed end and one open end. In the evaporation source 106, a crucible 102 filled with a material to be included in a film to be formed, and the crucible 102 is heated to vaporize the material. The closed tube 108 has a function to transport vapor of the material uniformly over the substrate on which the film is to be formed. Note that an element corresponding to the closed tube 108 may be called a head, a receiver, a tube, or a mixing chamber.

An example is shown in FIG. 1 in which a set of the evaporation source 106 and the closed tube 108 is installed in one chamber 200. However, the number of the set of the evaporation source 106 and the closed tube 108 can be arbitrarily determined, and a plurality of sets of the evaporation source 106 and the closed tube 108 may be provided, thereby making it possible to stack a plurality of films including materials different from one another. Additionally, co-evaporation can be performed, allowing the formation of a film including different materials.

The chamber 200 may have a wall and floor made of stainless steel and is connected to a vacuum pump (not illustrated) to keep the inside at a high vacuum. Furthermore, a pressure in the chamber 200 can be changed from a high vacuum to a normal pressure, and the chamber 200 may be configured so that the inside can be filled with an inert gas such as argon and nitrogen. As shown in FIG. 2, the chamber 200 may be composed of a plurality of treatment chambers which can be partitioned from one another with shutters 202 and 204. The film-forming apparatus 100 and the chamber 200 may be configured so that the substrate 140 and a metal mask 144 can be transported between the treatment chambers by operating the shutters 202 and 204.

The film-forming apparatus 100 may further possess a substrate holder 142 for holding the substrate 140. As shown in FIG. 1 and FIG. 2, the substrate holder 142 is able to hold the substrate 140 so that a main surface (a surface on which a film is to be formed) of the substrate 140 is arranged perpendicularly to a horizontal direction. The substrate holder 142 may be also configured to simultaneously hold the substrate 140 together with the metal mask 144. The metal mask 144 is placed between the substrate 140 and the evaporation source 106. The film-forming apparatus 100 may further include a magnet 146 as an optional structure in order to allow the metal mask 144 and the substrate 140 to be in close contact to each other and increase alignment accuracy of the metal mask 144. With the magnet 146, positional accuracy of the film to be formed can be increased.

As shown in FIG. 1, when the main surface of the substrate 140 is arranged so as to be perpendicular to a horizontal direction, an area occupied by the film-forming apparatus 100 can be remarkably reduced. Additionally, bending of the metal mask 144 due to its weight can be reduced, by which film-formation can be carried out at higher positional accuracy. However, the arrangement of the substrate 140 is not limited thereto, and the substrate holder 142 may be configured so that the main surface of the substrate 140 is disposed parallel to a horizontal direction. This mode is explained in the Second Embodiment.

The film-forming apparatus 100 may further include a deposition shutter 150. The deposition shutter 150 is provided to switch deposition of a material ON and OFF. Vapor of a material is capable of flying in a direction to the substrate 140 while the deposition shutter 150 is opened. On the other hand, when the deposition shutter 150 is closed, vapor of a material is blocked by the deposition shutter 150 and deposition of the material does not proceed. The deposition shutter 150 may be structured with a single metal plate or a plurality of metal plates so as to block a plurality of opening portions 134 of the closed tube 108.

The film-forming apparatus 100 may further possess a thickness monitor 152 for monitoring a thickness of a film to be formed over the substrate 140 and a holder 154 for holding the thickness monitor 152 (see FIG. 2). As described below, a plurality of thickness monitors 152 may be disposed. In this case, the plurality of thickness monitors 152 can be arranged perpendicularly to a horizontal direction.

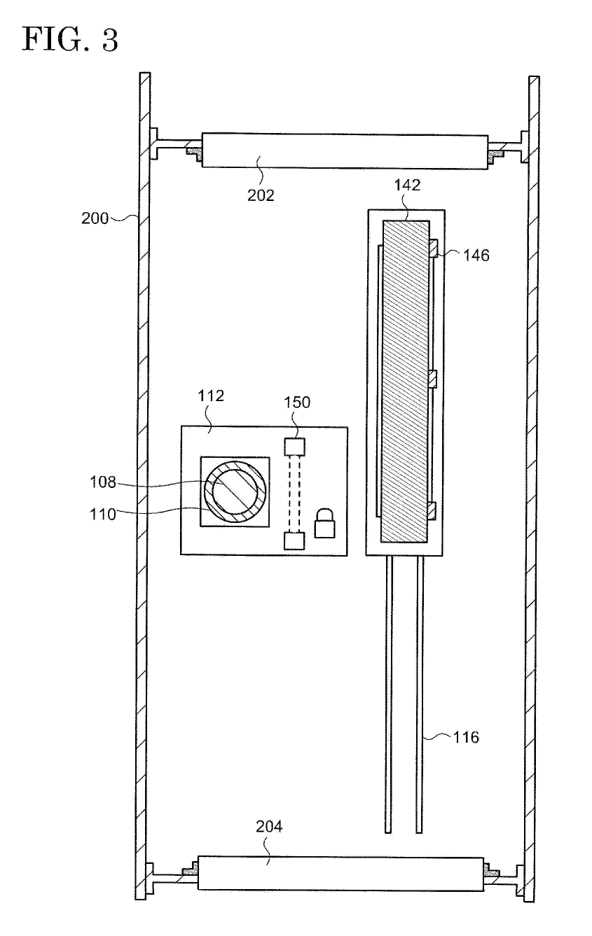

A mechanism for moving the substrate 140 relative to the evaporation source 106 can be provided in the chamber 200. The substrate 140 may be moved while fixing the evaporation source 106, or the evaporation source 106 may be moved while fixing the substrate 140. Alternatively, both of the substrate 140 and the evaporation source 106 may be moved simultaneously. For example, a transportation robot 114 which supports a supporting stand 112 equipped with the evaporation source 106 and the deposition shutter 150 and is capable of two-dimensionally moving the supporting stand 112 may be provided in the chamber 200 to move the evaporation source 106 as shown in FIG. 1 and FIG. 2. Alternatively, as shown in FIG. 3, the film-forming apparatus 100 may be configured so that a guide 116 functioning as rails is disposed under the substrate holder 142 to one-dimensionally move the substrate 140 relative to the evaporation source 106.

### 2. Evaporation Source

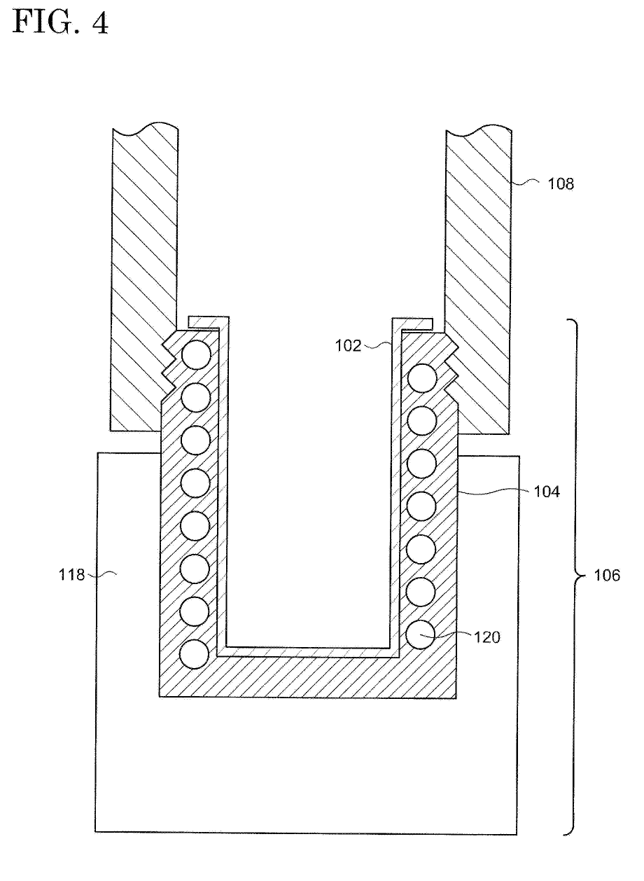

A schematic cross-sectional view of the evaporation source 160 is shown in FIG. 4. The evaporation source 106 has the vessel 104 capable of supporting the crucible 102 therein. The evaporation source 106 may further include an evaporation holder 118 for supporting the vessel 104 as an optional structure.

The crucible 102 is filled with a material subjected to evaporation and detachable from the vessel 104 or the evaporation holder 118. The crucible 102 may contain a metal such as tungsten, tantalum, molybdenum, titanium, and nickel or an alloy thereof. Alternatively, the crucible 102 may contain an inorganic insulator such as alumina, boron nitride, and zirconium oxide. As an optional structure, a mesh of a metal plate may be installed to an upper portion of the crucible 102 to avoid explosive scattering of the material.

The vessel 104 can be configured to heat the crucible 102 with a resistive heating method. That is, a heater 120 is installed in the vessel 104, and a current is supplied to the heater 120 to heat the vessel 104, by which a material in the crucible 102 can be heated and vaporized. Similar to the crucible 102, the vessel 104 and the evaporation holder 118 may contain the aforementioned metal, alloy thereof, or inorganic insulator.

A material is vaporized in the crucible 102, and its vapor is supplied into the closed tube 108 from the evaporation source 106 (from the crucible 102). A connection mode between the closed tube 108 and the evaporation source 106 is arbitrary. For example, the closed tube 108 and the vessel 104 may have a relationship of an external screw and an internal screw, and the vessel 104 may be screwed into the closed tube 108 as shown in FIG. 4. Alternatively, the closed tube 108 may be simply put over the evaporation source 106 without applying the aforementioned fixing method.

A material to be vaporized may be selected from a variety of materials and may be an organic compound or an inorganic compound. For example, an emissive material or a carrier-transporting organic compound may be used as an organic compound. A metal, an alloy thereof, or a metal oxide may be employed as an inorganic compound. Film-formation may be performed by filling one crucible 102 with a plurality of materials. An appropriate use of these materials to three-dimensionally construct a plurality of films allows production of a variety of semiconductor elements such as an organic transistor, a light-emitting element, a memory element, and a laser element.

### 3. Closed Tube

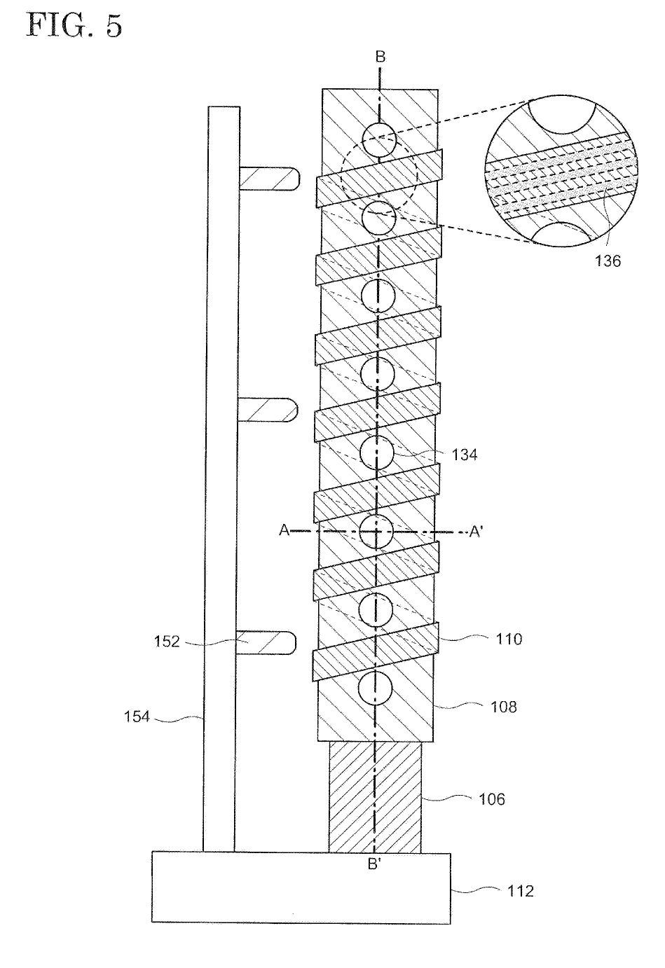

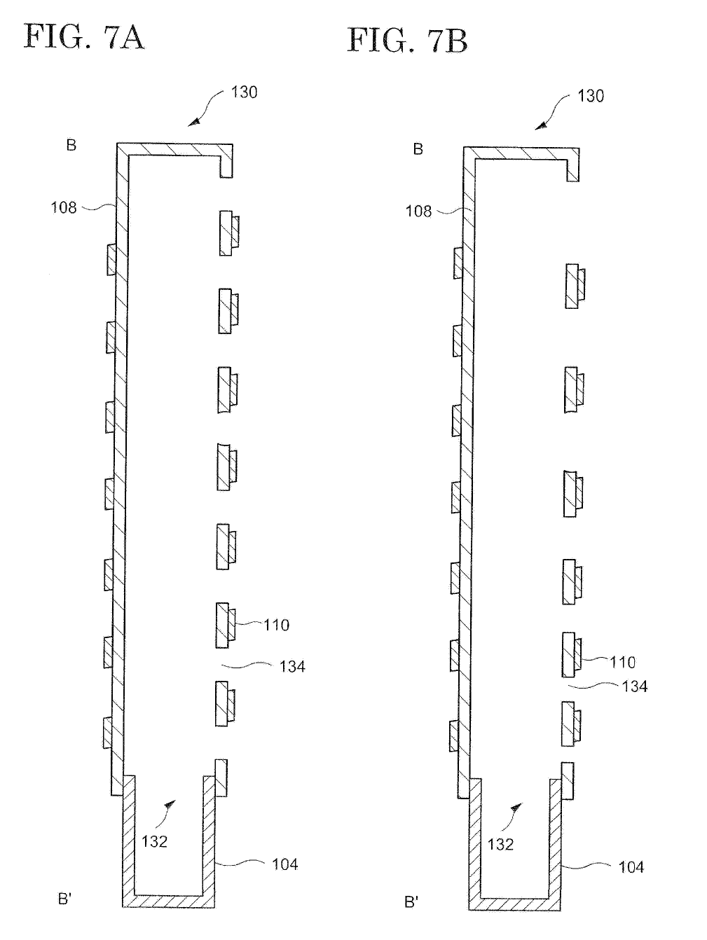

A side view of the closed tube 108 is shown in FIG. 5. FIG. 5 is a schematic view when the closed tube 108 is observed from a side of the substrate holder 142. Cross-sectional views along a chain line A-A′ and B-B′ of FIG. 5 are illustrated in FIG. 7A and FIG. 7B, respectively.

As shown in FIG. 5, FIG. 7A, and FIG. 7B, the closed tube 108 is a tube having a closed end portion (closed end) 130 at one end and an open end portion (open end) 132 at the other end and is placed over the vessel 104 of the evaporation source 106 so as to cover the vessel 104. In this case, the open end 132 is connected to the vessel 104 so that vapor of a material is supplied into the closed tube 108 (see FIG. 4). The closed tube 108 may be arranged so that its longitudinal direction is perpendicular to a horizontal direction. The closed tube 108 has the plurality of opening portions 134, and the opening portions 134 are arranged so as to face the substrate holder 142 as shown in FIG. 5. That is, the opening portions 134 are provided on a side surface of the closed tube 108 close to the substrate holder 142. As shown in FIG. 7A, the opening portions 134 may be disposed with a uniform interval therebetween. Alternatively, the opening portions 134 may be formed so that an interval between the adjacent opening portions 134 increases stepwise or continuously as shown in FIG. 7B. In FIG. 7B for example, the opening portions 134 are arranged so that an interval between the adjacent opening portions 134 is small on a side of the open end 132, while an interval between the adjacent opening portions 134 is large on a side of the closed end 130.

The closed tube 108 may include a variety of materials typified by a metal such as titanium, tungsten, tantalum, molybdenum, and nickel and an alloy such as stainless steel. A length of the closed tube 108 in the longitudinal direction may be approximately the same as a height of the substrate 140 when the substrate 140 is arranged so that its main surface is perpendicular to a horizontal direction. That is, the length of the closed tube 108 in the longitudinal direction the can be equal to or larger than 0.5 times and equal to or smaller than 1.5 times or equal to or larger than 0.8 times and equal to or smaller than 1.2 times the aforementioned height.

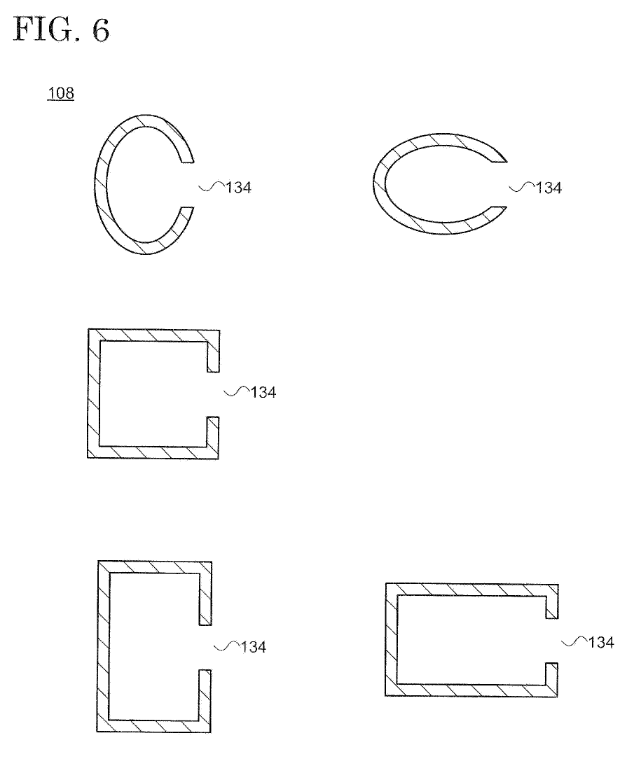

As shown in FIG. 6, a shape of the closed tube 108, namely, a shape of a cross-section of the closed tube 108 perpendicular to the longitudinal direction is not limited, and the cross section can possess a variety of shapes such as an ellipse, square, and rectangle in addition to a circle. When the cross section is rectangular, the opening portions 134 may be formed on a long side or a short side. When the cross section is an ellipse, the opening portions 134 may be parallel to the long side or the short side.

When a material is vaporized in the evaporation source 106, the vapor is supplied into the closed tube 108 from the crucible 102. After that, the vapor passes through the opening portions 134, ejects from the closed tube 108, and flies to the substrate 140 held by the substrate holder 142. The vapor is cooled and solidified upon contact with the substrate 140, and the material is deposited, resulting in the formation of a film of the material over the substrate 140. As mentioned above, the length of the closed tube 108 in the longitudinal direction can be approximately the same as the height of the substrate 140 employed, and the plurality of the opening portions 134 may be arranged to face the substrate 140 with a uniform interval. Hence, even when a large substrate 140 is used, a film with a uniform thickness can be prepared.

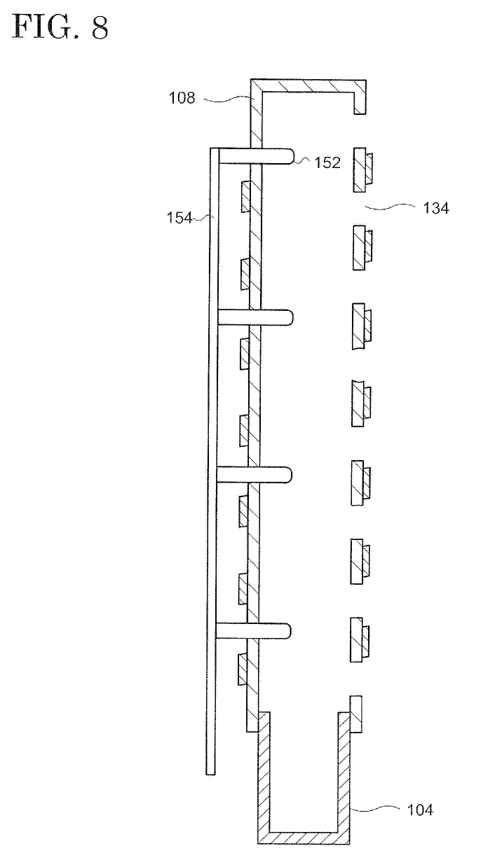

The thickness of the film to be prepared can be controlled with the thickness monitor 152. As the thickness monitor 152, a quartz oscillator can be used, for example. At least one thickness monitor 152 may be disposed at a position which contacts with the vapor of the material ejected from the opening portions 134. However, as shown in FIG. 5, a plurality of thickness monitors 152 may be arranged in a direction perpendicular to a horizontal direction, by which the thickness of the film can be monitored and controlled over the whole of the substrate 140. Note that, as shown in FIG. 8, one or a plurality of thickness monitors 152 may be installed in the closed tube 108 to estimate the thickness of the film to be prepared.

### 4. Sheet-Shaped Heater

In the aforementioned evaporative deposition process, the heating and vaporization of a material are performed in the chamber 200 in which a high vacuum is maintained. Additionally, heat for heating the material is supplied by the evaporation source 106. Therefore, heat conduction is a main mechanism in conveying heat from the evaporation source 106 to the closed tube 108. Hence, a temperature gradient may be generated in the closed tube 108 due to the heat conduction mechanism. For example, a high temperature capable of vaporizing a material can be kept on a side close to the open end 132, while the material cannot maintain a gas state and solidify on a side close to the closed end 130, resulting in a block of the opening portions 134. On the other hand, when the evaporation source 106 is heated so that the side close to the closed end 130 has a temperature sufficient for preventing the block of the opening portions 134, pyrolysis of the material may occur in the crucible 102.

Hence, a sheet-shaped heater 110 is wound around the closed tube 108 in the film-forming apparatus 100 of the present embodiment. For example, the sheet-shaped heater 110 may be disposed so as to wind around the outside of the closed tube 108 as shown in FIG. 5. In the example shown in FIG. 5, the sheet-shaped heater 110 helically winds around the outside of the closed tube 108. In this case, the sheet-shaped heater 110 is arranged to avoid the opening portions 134, that is, to pass between the adjacent opening portions 134, by which the temperature gradient of the closed tube 108 can be solved. Accordingly, it is possible to maintain a uniform temperature over the whole of the closed tube 108, and the vapor of a material can be ejected at a uniform rate from the plurality of opening portions 134 without blocking the opening portions 134. Hence, a film with a uniform thickness can be prepared over the whole of the substrate 140.

In the sheet-shaped heater 110, an electrical heating wire 136 which generates heat when supplied with electricity is enclosed by a noncombustible polymer such as glass fiber and an aromatic polyamide or polyimide (see, an enlarged figure of FIG. 5), and its flexibility allows it to be installed on a variety of places in a variety of configurations. The sheet-shaped heater 110 may have a ribbon shape depending on its shape and can be called a ribbon-shaped heater. In the present specification and claims, the sheet-shaped heater 110 is defined as including a ribbon-shaped heater. Note that a heater without a sheet shape (e.g., tube-shaped heater) may be wound around the closed tube 108 instead of the sheet-shaped heater 110.

Since the sheet-shaped heater 110 has a small thickness, the flight of the material ejected from the opening portions 134 is not affected, which contributes to uniformness of the thickness of a film to be formed. Furthermore, since the sheet-shaped heater 110 can be readily attached to and detached from the closed tube 108, it can be readily exchanged when a material is attached, thereby decreasing a suspension period of the film-forming process. Moreover, the sheet-shaped heater 110 undergoes surface contact with an object to be heated, by which the closed tube 108 can be efficiently heated.

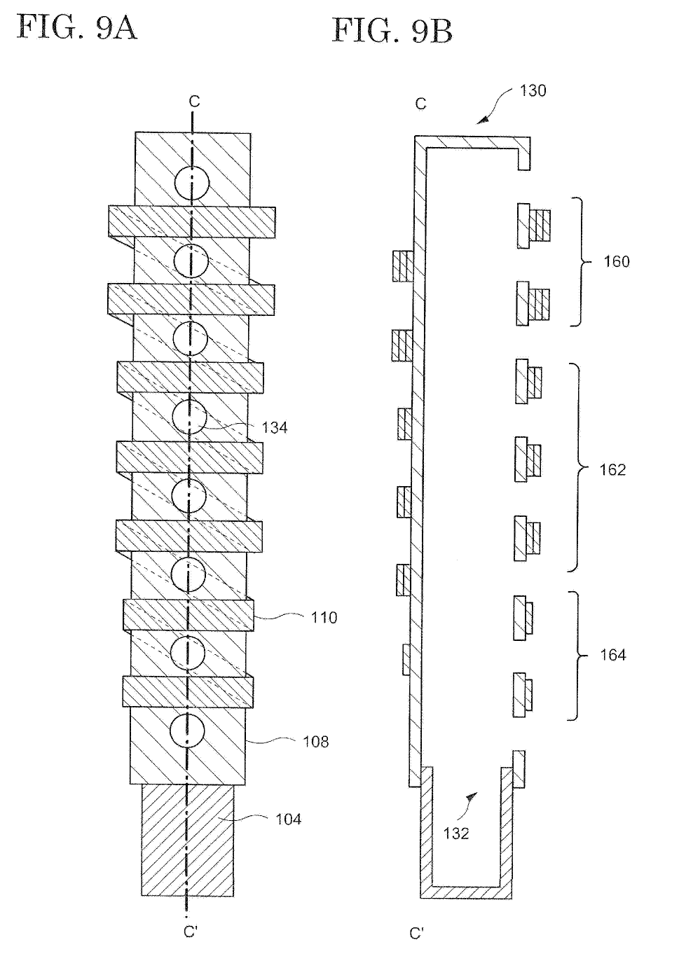

Additionally, the sheet-shaped heater 110 can be installed in a variety of modes due to flexibility. In view of a vapor pressure and a melting point of a material and the length and temperature gradient of the closed tube 108, it is preferred to install the sheet-shaped heater 110 to the closed tube 108 ununiformly (or at an ununiform density) between the side of the open end 132, i.e., a side on which the evaporation source 106 is positioned, and the side opposite to the open end 132 (the side of the closed end 130), i.e., a side opposite to the evaporation source 106. In other words, it is preferred that the configuration (arrangement state) of the sheet-shaped heater 110 be varied with increasing distance from the evaporation source 106. For example, as shown in FIG. 9A and FIG. 9B which is a cross-sectional view along a chain line C-C′ of FIG. 9A, the sheet-shaped heater 110 may possess a portion in which the sheet-shaped heater 110 overlaps at the same position or a portion in which the sheet-shaped heater 110 is wound while overlapping with itself. In this case, the sheet-shaped heater 110 may be stacked at the same position to increase a winding number (overlapping number) on the side of the closed end 130, and the winding number may be decreased continuously or stepwise in a direction to the open end 132. In other words, the winding number may be increased with increasing distance from the open end 132. In FIG. 9A and FIG. 9B, an example is shown in which the winding number is 3 in a region 160 close to the closed end 130, the winding number is 1 in a region 164 close to the open end 132, and the winding number is 2 in a region 162 between these regions.

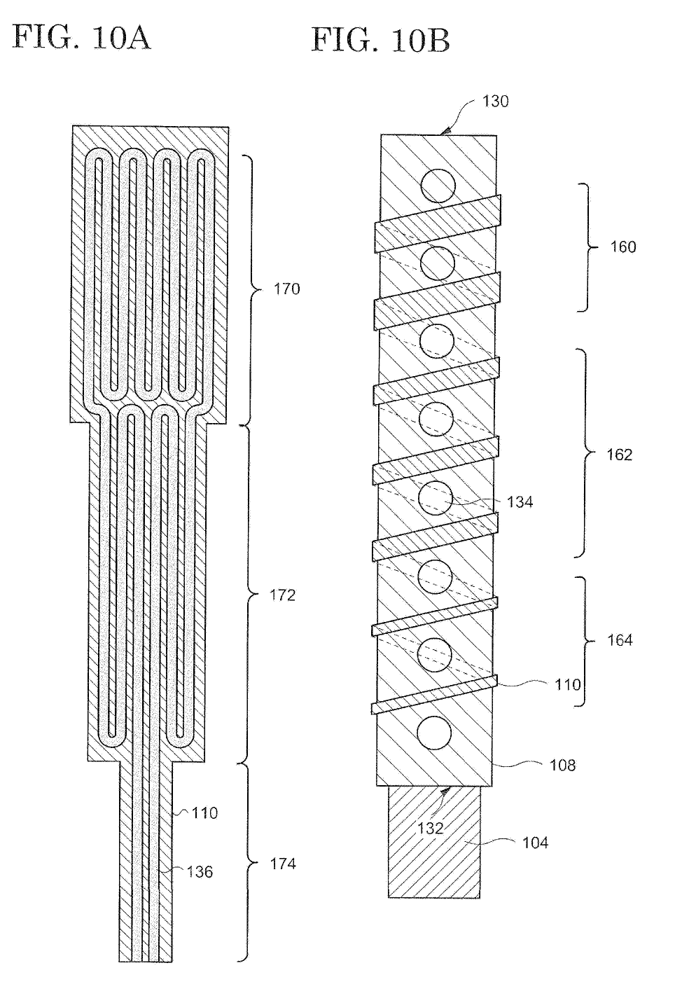

Alternatively, the temperature gradient of the closed tube 108 may be solved by changing a width of the sheet-shaped heater 110. In this case, a sheet-shaped heater 110 having regions different in length or folding number of the electrical heating wire 136 can be used as shown in FIG. 10A. Here, the sheet-shaped heater 110 has three regions 170, 172, and 174. The electrical heating wire 136 is the longest and has the largest folding number in the region 170 (folded 7 times in FIG. 10A). On the other hand, the heating wire 136 is the shortest and has the smallest folding number in the region 174 (folded 0 times in FIG. 10A). The length and the folding number of the electrical heating wire 136 are both between those of the regions 170 and 174 in the region 172 between the regions 170 and 174. Moreover, the width of the sheet-shaped heater decreases in the order of the regions 170, 172, and 174.

The use of such a sheet-shaped heater 110 allows the width of the sheet-shaped heater 110 passing between the opening portions 134 to be changed continuously or stepwise with a change in distance from the vessel 104 (evaporation source 106) as shown in FIG. 10B. In FIG. 10B, the width of the sheet-shaped heater 110 increases with increasing distance from the open end 132. Specifically, the width of the sheet-shaped heater 110 is the smallest in the region 164 close to the open end 132, the largest in the region 160 close to the closed end 130, and between those of these regions in the region 162 between the regions 160 and 164. Therefore, the length of the electrical heating wire 136 is also the shortest in the region 164 close to the open end 132, the longest in the region 160 close to the closed end 130, and between those of the regions 160 and 164 in the region 162 between the region 160 and 164.

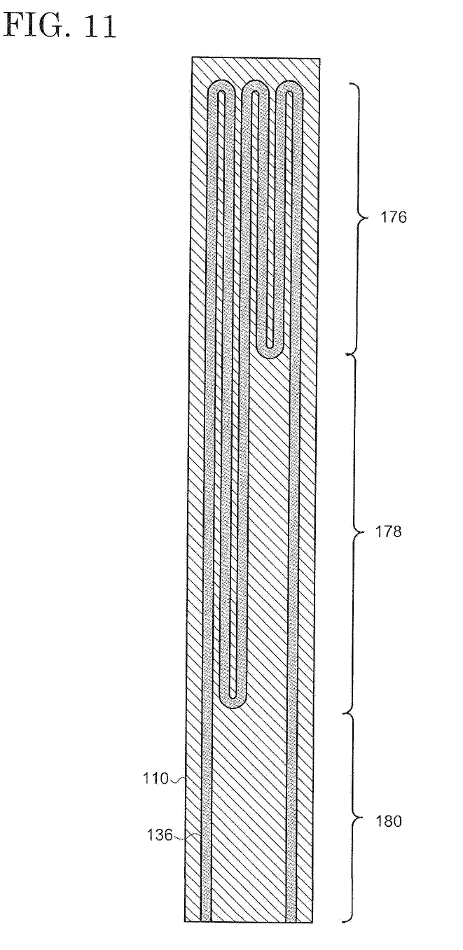

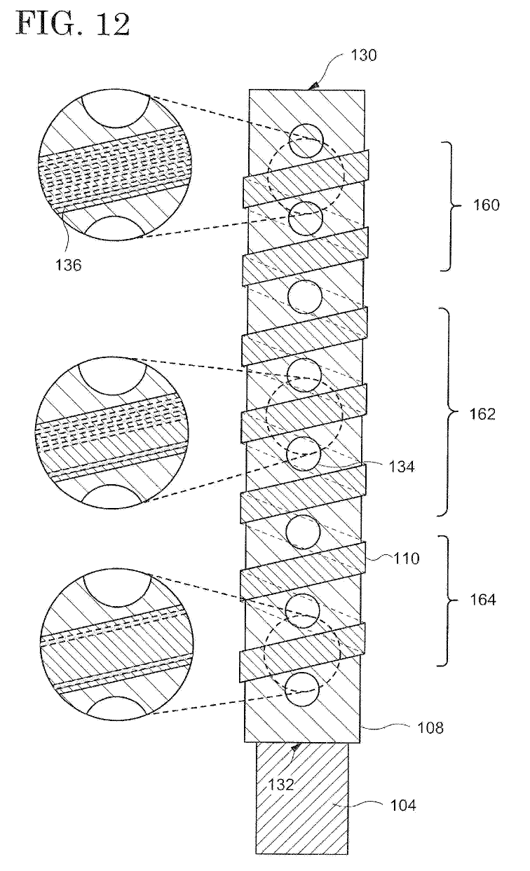

As shown in FIG. 11, the temperature gradient of the closed tube 108 may be solved by changing the length or the folding number of the electrical heating wire 136 installed in the sheet-shaped heater 110 without changing the width of the sheet-shaped heater 110. Here, the sheet-shaped heater 110 has two regions 176 and 180 with a region 178 interposed therebetween. The length and the folding number of the installed electrical heating wire 136 change in the order of the regions 180, 178, and 176. As shown in FIG. 12, although the width of the sheet-shaped heater 110 is the same in the regions 160, 162, and 164, the use of such a sheet-shaped heater 110 makes it possible to change the length of the electrical heating wire 136 of each region. Specifically, the length of the electrical heating wire 136 is shortest in the region 164 close to the open end 132, the longest in the region 160 close to the closed end 130, and between them in the region 162 which is between the regions 160 and 164. Note that, as shown in FIG. 12, the interval of the electrical wiring 136 may not be uniform in each region.

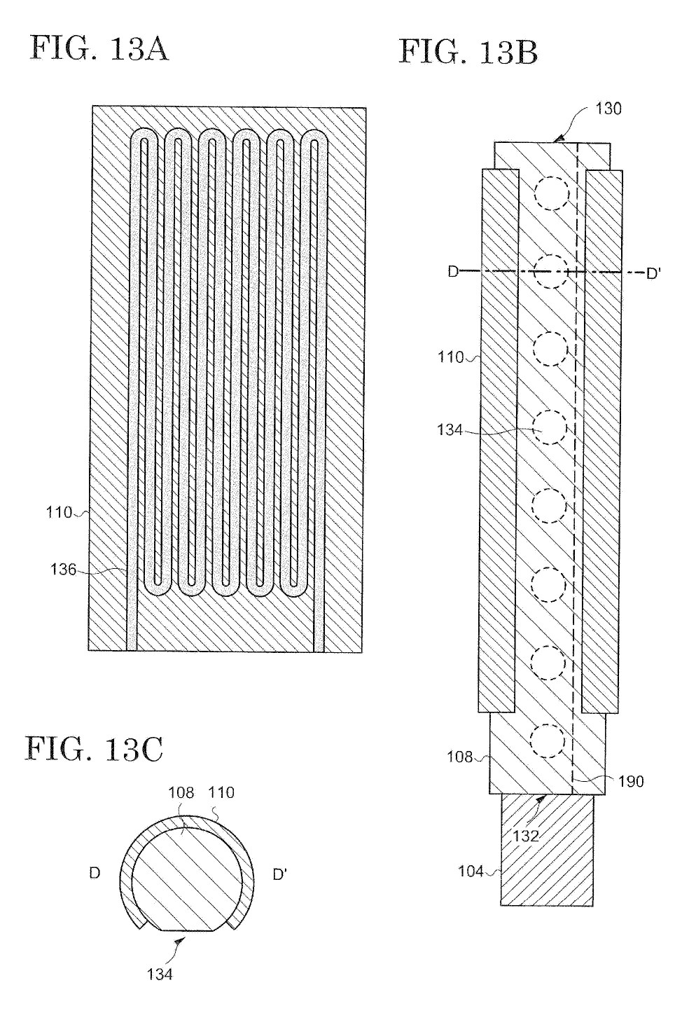

The sheet-shaped heater 110 may not be necessarily wound helically around the closed tube 108 but may be wound around a part of the closed tube 108 so that whole of the regions between the opening portions 134 are exposed. For example, the closed tube 108 may be covered with the sheet-shaped heater 110 shown in FIG. 13A (FIG. 13B, FIG. 13C). In this case, a part of the infinite straight lines located on the surface of the closed tube 108 and passing through the open end 132 and the closed end 130, e.g., a straight line 190 on the surface of the closed tube 108, is not covered by the sheet-shaped heater 110 but exposed. Additionally, in a cross-section along a broken line D-D′ of FIG. 13B, the sheet-shaped heater 110 gives an arch at a periphery of the closed tube 108, and the opening portion 134 is arranged at an opening of the arch.

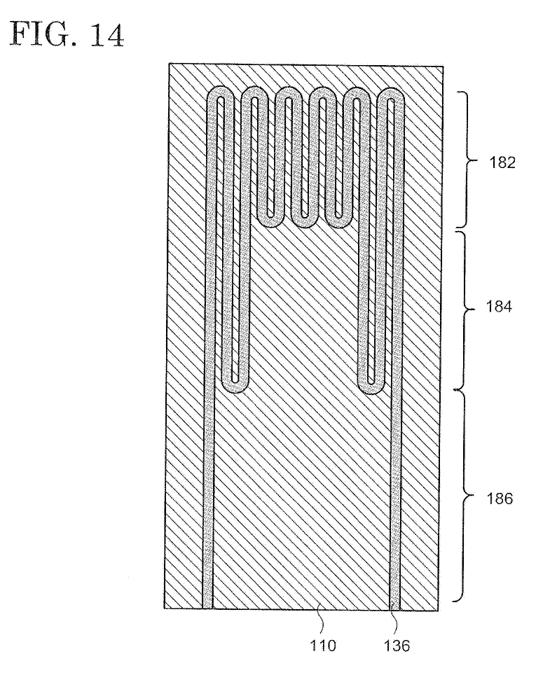

Similar to the aforementioned case, a plurality of regions in which the folding number or the length of the electrical heating wire 136 is different can be also provided to the sheet-shaped heater 110 in this case. For example, the sheet-shaped heater 110 may possess a region 182 with the largest folding number of the electrical heating wire 136, a region 186 with the smallest one, and a region 184 sandwiched by these regions and having the length and the folding number of the electrical heating wire 136 between those of the regions 182 and 186 as shown in FIG. 14.

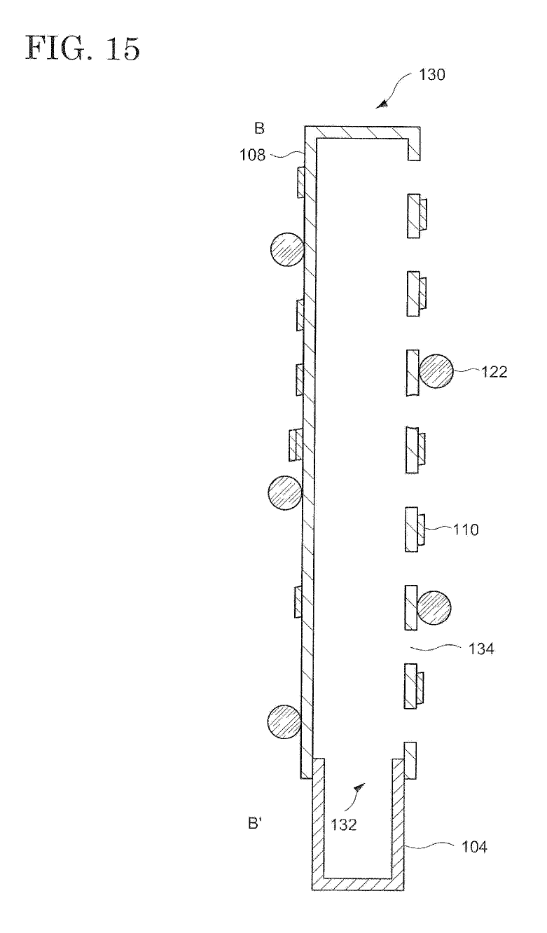

A heater other than the sheet-shaped heater 110 may be additionally provided to the closed tube 108 in addition to the sheet-shaped heater 110. The additional heater may be fixed to the closed tube 108. For example, a tube-shaped heater 122 for heating the closed tube 108 may be disposed as shown in FIG. 15. The tube-shaped heater 122 can be operated independently from the heater 120 for heating the crucible 102. The sheet-shaped heater 110 may be wound around the closed tube 108 in order to solve the temperature gradient of the closed tube 108 caused by heating with the tube-shaped heater 122

As described above, the sheet-shaped heater 110 can be arranged in a variety of modes, by which the temperature of the region 160 close to the closed end 130 can be increased, the block of the opening portions 134 can be prevented, and the temperature gradient can be solved. As a result, a material can be ejected from each opening portion 134 at a uniform rate, and therefore, a film with a uniform thickness can be fabricated over the substrate 140. Note that, instead of the sheet-shaped heater 110, the closed tube 108 may be equipped with a heater without a sheet shape (e.g., a tube-shaped heater) in the configuration and arrangement which are the same as those of the sheet-shaped heater 110 explained in FIG. 1 to FIG. 15.

In view of a solution of the temperature gradient, the ununiform configuration (arrangement state) of the sheet-shaped heater 110 explained in FIG. 9A to FIG. 14 may be reversed between the evaporation source 106 side (vessel 104 side) and the side opposed to the evaporation source 106. Specifically, the winding number of the sheet-shaped heater 110 may be increased on the side of the evaporation source 106 and decreased on the side opposite to the evaporation source 106. Furthermore, the width of the sheet-shaped heater 110 may be increased on the side of the evaporation source 106 and decreased on the side opposite to the evaporation source 106. This is because, when the longitudinal direction of the closed tube 108 is arranged perpendicularly to a horizontal direction, an upper side of the closed tube 108 may have a higher temperature than a lower side.

### 5. Film-Forming Method

When an evaporative deposition is carried out by using the film-forming apparatus 100, the crucible 102 is filled with a material to be evaporated, and the crucible 102 is set in the vessel 104. After connecting the vessel 104 to the closed tube 108, the sheet-shaped heater 110 is wound around the closed tube 108. After that, a current is supplied to the heater 120 in the vessel 104 to start heating the crucible 102. At the same time, a current is also provided to the sheet-shaped heater 110 to heat the closed tube 108. The electricity may be controlled so that the temperature of the closed tube 108 is the same as or higher than the temperature of the crucible 102, by which the temperature gradient of the closed tube 108 is solved and the block of the opening portions 134 can be effectively prevented.

The substrate 140 is set at the substrate holder 142 so that the main surface is perpendicular to a horizontal direction. If necessary, the metal mask 144 is arranged between the substrate holder 142 and the closed tube 108. The evaporation rate is estimated with the thickness monitor 152, and the deposition shutter 150 is opened to start deposition when a predetermined evaporation rate is obtained to start deposition. In this case, one or both of the evaporation source 106 with the closed tube 108 and the substrate holder 142 are moved by utilizing the transportation robot 114 or the guide 116 in order that the vapor of the material is attached to the whole surface of the substrate 140. The deposition shutter 150 is closed after a film with a predetermined thickness is obtained to stop deposition of the material, by which the film of the material can be formed over the substrate 140. Repetition of the process while changing the material enables a plurality of different films to be stacked. Additionally, the use of a plurality of the evaporation sources 106 and closed tubes 108 placed thereover in formation of a film (co-evaporation) gives the film including a plurality of materials.

Film-formation with the film-formation apparatus 100 described in the present embodiment prevents the block of the opening portions 134 with a material, by which film-formation can be efficiently performed. Additionally, the film-formation is carried out while the substrate 140 is disposed so that its main surface is perpendicular to a horizontal direction. Therefore, not only an area occupied by the film-forming apparatus 100 can be reduced but also the bending of the metal mask 144 can be prevented, by which accurate film-formation can be realized. Moreover, vapor of a material is ejected to the substrate 140 by using the closed tube 108 having a length substantially the same as the height of the substrate 140. In this case, the evaporation source 106 and the substrate 140 are relatively moved, and the attachable and detachable sheet-shaped heater 110 is installed in order to solve the temperature gradient of the closed tube 108. Hence, a film with a uniform thickness can be fabricated even if a large-size substrate 140 is employed, leading to the production of a semiconductor element with small variation and a semiconductor device including the same.

### Second Embodiment

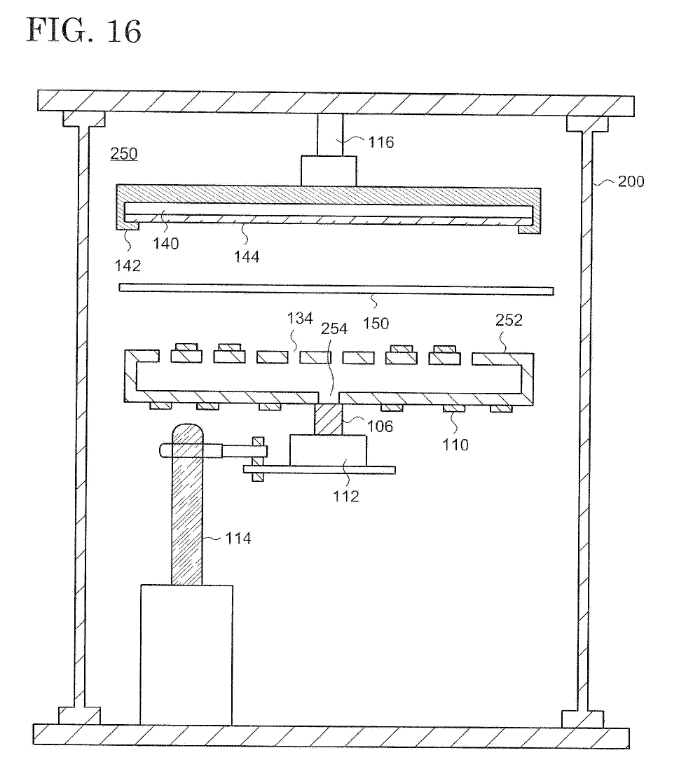

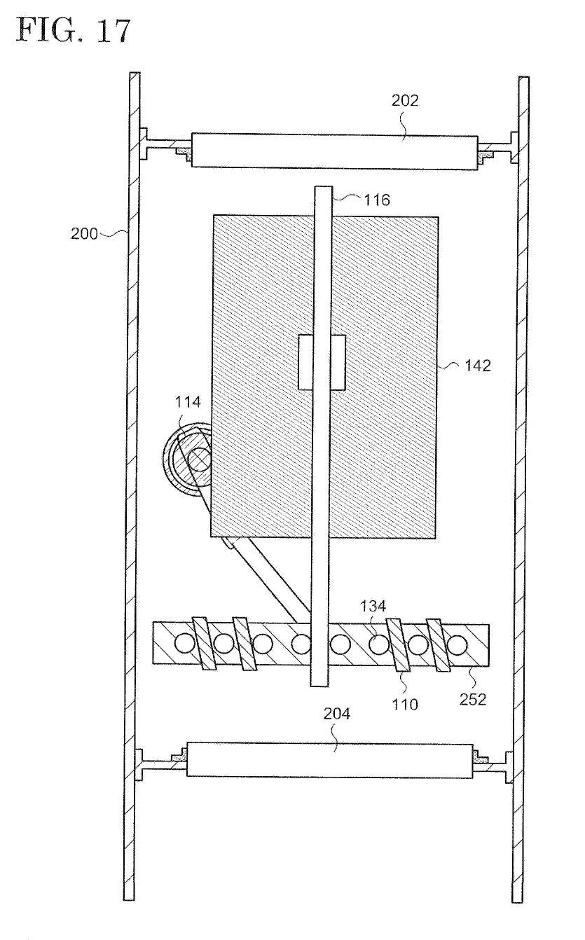

In the present embodiment, explanation is given by using FIG. 16 and FIG. 17 with respect to a film-forming apparatus 250 for forming a film while holding the substrate 140 so that the main surface of the substrate 140 is parallel to a horizontal direction. The structures the same as those of the First Embodiment may be omitted.

FIG. 16 is a side view of the film-forming apparatus 250. The film-forming apparatus 250 has the substrate holder 142 for holding the substrate 140, the evaporation source 106 located under the substrate holder 142, and a head 252 provided over the evaporation source 106. The head 252 has an opening portion 254 in a bottom portion and is connected to the evaporation source 106. The evaporation source 106 may have the same structure as that of the evaporation source 106 of the First Embodiment. Hence, vapor of a material is supplied into the head 252 through the opening portion 254.

A plurality of opening portions 134 is provided in an upper portion of the head 252. These opening portions 134 correspond to the opening portions 134 of the closed tube 108 of the First Embodiment, and vapor of a material is ejected in a direction to the substrate 140 through the opening portions 134. The deposition shutter 150 is arranged between the head 252 and the substrate holder 142. As shown in FIG. 17, the longitudinal direction of the head 252 is arranged parallel to a horizontal direction, and its length can be substantially the same as a long side or a short side of the substrate 140 employed. For example, the length of the longitudinal direction of the head 252 can be 0.5 times to 1.5 times or 0.8 times to 1.2 times the long side or the short side of the substrate 140.

Similar to the film-formation apparatus 100, the film-forming apparatus 250 may have a mechanism for relatively moving the head 252 and the substrate 140 during the film formation. For example, the head 252 may be configured to be two-dimensionally moved in the chamber 200 by using the transportation robot 114. On the other hand, the substrate holder 142 may be configured to be moved one-dimensionally along the guide 116 installed in the chamber 200.

Note that, although not illustrated, a heater such as the tube-shaped heater 122 of the First Embodiment may be additionally attached to the head 252.

The film-forming apparatus 250 may possess the sheet-shaped heater 110 wound around the head 252 (FIG. 16, FIG. 17). The sheet-shaped heater 110 is attachable and detachable, capable of reducing the temperature distribution of the head 252, has a function to solve the temperature gradient, and corresponds to the sheet-shaped heater 110 provided to the closed tube 108 of the film-forming apparatus 100. Since heating of the head 252 with the sheet-shaped heater 110 prevents the block of the opening portions 134 with a material, film formation can be performed efficiently. Additionally, the evaporation source 106 and the substrate 140 are relatively moved, and the attachable and detachable sheet-shaped heater 110 is disposed to solve the temperature gradient of the head 252. Hence, a film with a uniform thickness can be fabricated even if a large-size substrate 140 is used, leading to the production of a semiconductor element with small variation and a semiconductor device including the same.

Similar to the First Embodiment, it is preferred that the sheet-shaped heater 110 be attached to the head so as to be ununiformly arranged between the side on which the evaporation source 106 is positioned and the side opposite to the evaporation side 106. In other words, it is preferred to change the configuration (arrangement state) of the sheet-shaped heater 110 as a distance from the evaporation source 106 is increased. Specifically, it is preferred to attach the sheet-shaped heater 110 to the head 252 while making the winding number and the width of the sheet-shaped heater 110 ununiform similar to those of the First Embodiment.

### Third Embodiment

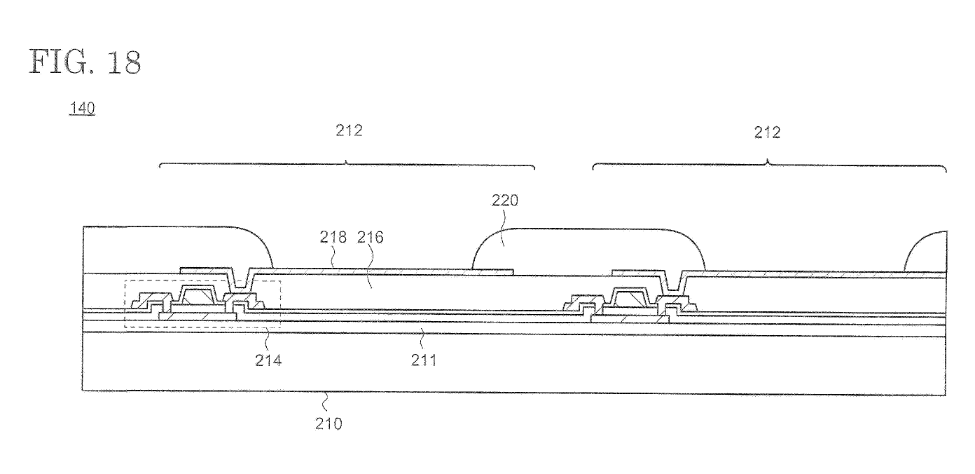

In the present embodiment, explanation is provided by using FIG. 18 to FIG. 23 with respect to a manufacturing method of a display device equipped with a light-emitting element as a semiconductor element, which is applied with the film-forming apparatus 100 and the film-forming method described in the First Embodiment.

The display device can be manufactured by stacking a plurality of thin films including organic compounds over the substrate 140 by utilizing the film-forming apparatus 100 described in the First Embodiment. As shown in FIG. 18, the substrate 140 has a supporting substrate 210 including glass or quartz and a plurality of pixels 212 formed thereover. The supporting substrate 210 may be structured with a glass substrate and a resin film (resin substrate) formed over the glass substrate. In this case, the glass substrate is peeled off from the substrate 140 or the display device in a latter process. In FIG. 18, two adjacent pixels 212 are illustrated. At least one switching element such as a transistor is provided in each pixel 212. An example is shown in FIG. 18 in which a top-gate type transistor 214 is formed as an example of a transistor in each pixel 212. However, the structure of the transistor 214 is not limited thereto, and a bottom-gate type transistor may be used. In FIG. 18, a base film 211 which is an inorganic film including silicon nitride (SiN), for example, is disposed over the supporting substrate 210. The transistor 214 is formed over the base film 211.

A leveling film 216 absorbing depressions and projections caused by the transistor 214 and the like and giving a flat top surface is provided over the transistor 214. A pixel electrode 218 is electrically connected to the transistor 214 through an opening portion formed in the leveling film 216. The pixel electrode 218 functions as one electrode of the light-emitting element. A partition wall 220 including an insulator is arranged at an edge portion of the pixel electrode 218. The partition wall 220 covers the edge portion of the pixel electrode 218 and demarcates adjacent pixels 212 from each other.

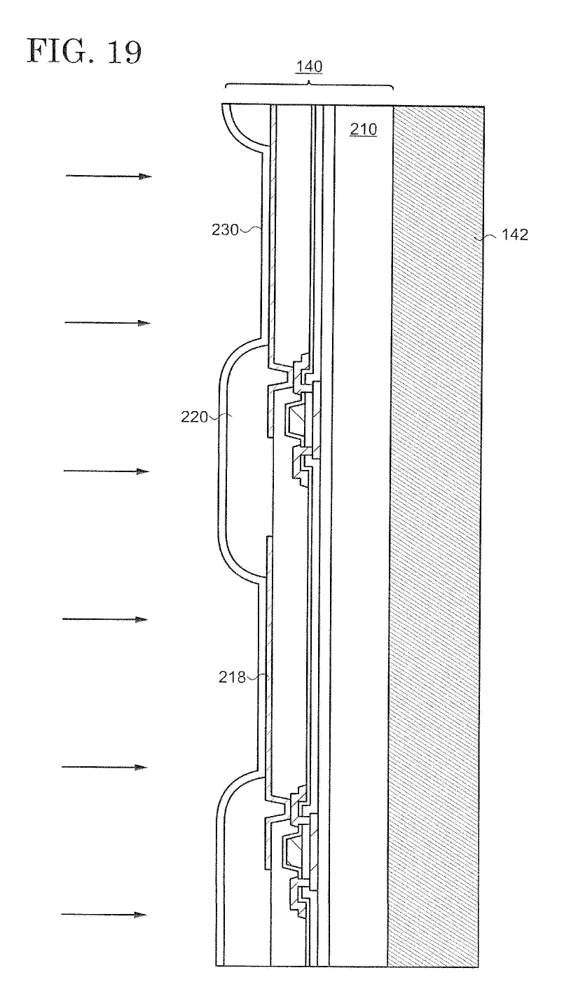

The substrate 140 is set on the substrate holder 142 of the film-forming apparatus 100 described in the First Embodiment (see FIG. 1 and FIG. 19). Here, a surface to which the pixel electrode 218 is provided is the main surface of the substrate 140, and the substrate 140 is arranged vertically so that the main surface faces the closed tube 108 (FIG. 19).

First, a first carrier-injection/transporting layer 230 is formed as a layer in contact with the pixel electrode 218. The carrier-injection/transporting layer 230 can be formed so as to extend over the plurality of pixels 212. Thus, the metal mask 144 is placed between the substrate 140 and the closed tube 108 so as to shield a region where the pixel electrode 212 is not provided. Therefore, the metal mask 144 is not illustrated in FIG. 19. In FIG. 19, the carrier-injection/transporting layer 230 is illustrated as a single layer. However, the carrier-injection/transporting layer 230 may include a plurality of layers. When the pixel electrode 218 is employed as an anode, a material to which holes are readily injected and which has a high hole mobility is used for the first carrier-injection/transporting layer 230. For example, an aromatic amine is a representative material. The carrier-injection/transporting layer 230 may be formed by co-evaporating these materials with a compound with an electron-accepting property.

The crucible 102 is filled with a material forming the carrier-injection/transporting layer 230 and installed in the vessel 104. The closed tube 108 is disposed over the evaporation source 106. Heating is performed by operating the heater 120 while maintaining the inside of the chamber 200 at a high vacuum. At the same time, the closed tube 108 is heated by applying a current to the sheet-shaped heater 110 in order to avoid generation of the temperature gradient and the block of the opening portions 134.

When the material is vaporized, its vapor is supplied to the closed tube 108 and then ejected from the opening portions 134. The ejected vapor flies in the direction of the substrate 140, contacts with the pixel electrode 218, and solidifies, resulting in the formation of the first carrier-injection/transporting layer 230 (see FIG. 19). The first carrier-injection/transporting layer 230 may also be formed over the partition wall 220. Through these processes, the first carrier-injection/transporting layer 230 is evaporatively deposited.

An emission layer is sequentially formed. When the same emission layer is shared by all of the pixels 202 over the substrate 140, the metal mask 144 used in the formation of the first carrier-injection/transporting layer 230 may be employed to form the emission layer over the first carrier-injection/transporting layer 230. In this case, the emission layer is also formed over the partition wall 220 through the first carrier-injection/transporting layer 230.

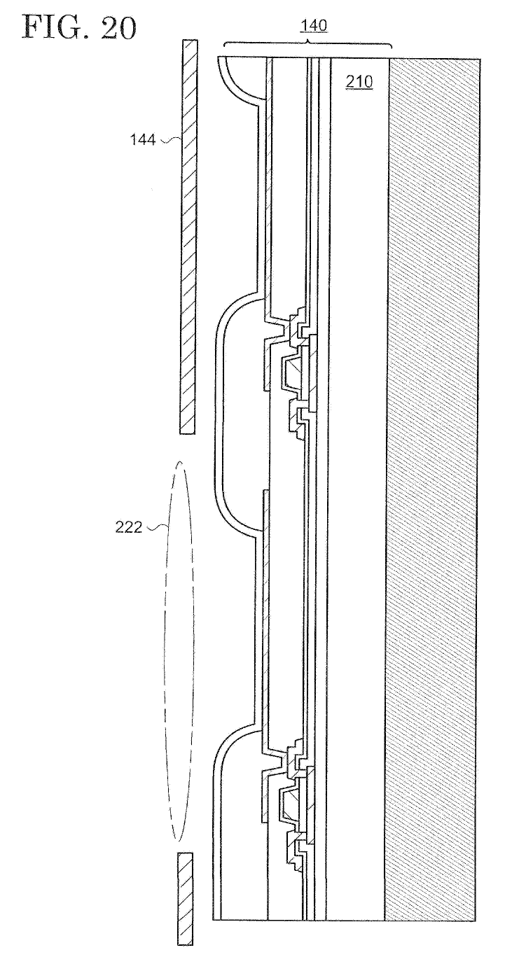

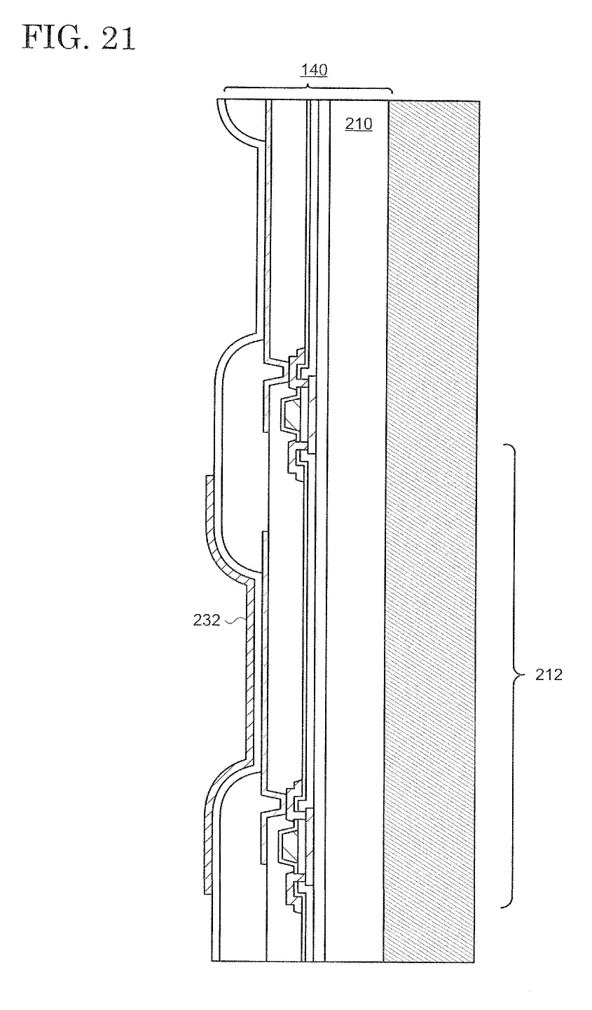

On the other hand, when different emission colors are obtained between two adjacent pixels 212, a metal mask 144 for the side-by-side deposition is utilized to individually form each emission layer. Specifically, as shown in FIG. 20, the metal mask 144 having an opening portion 222 in a region where the first emission layer 232 is to be formed is arranged between the substrate 140 and the closed tube 108. The crucible 102 is filled with a material for giving the first emission layer 232, and the first emission layer 232 is evaporatively deposited similar to the evaporative deposition of the first carrier-injection/transporting layer 230 (see, FIG. 21). With this process, the first emission layer 232 is selectively formed in the respective pixel 212 (the pixel 212 located under the opening portion 222).

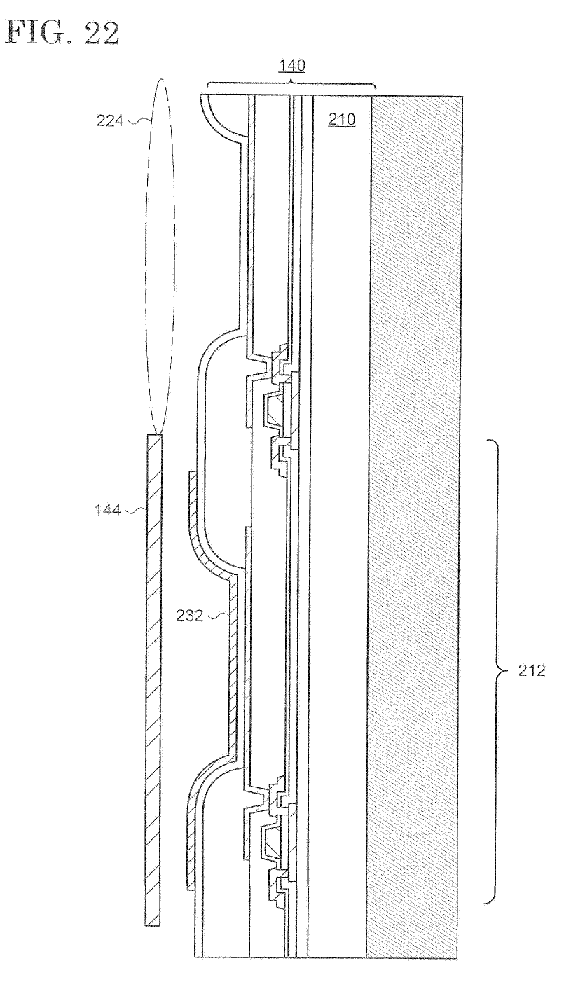

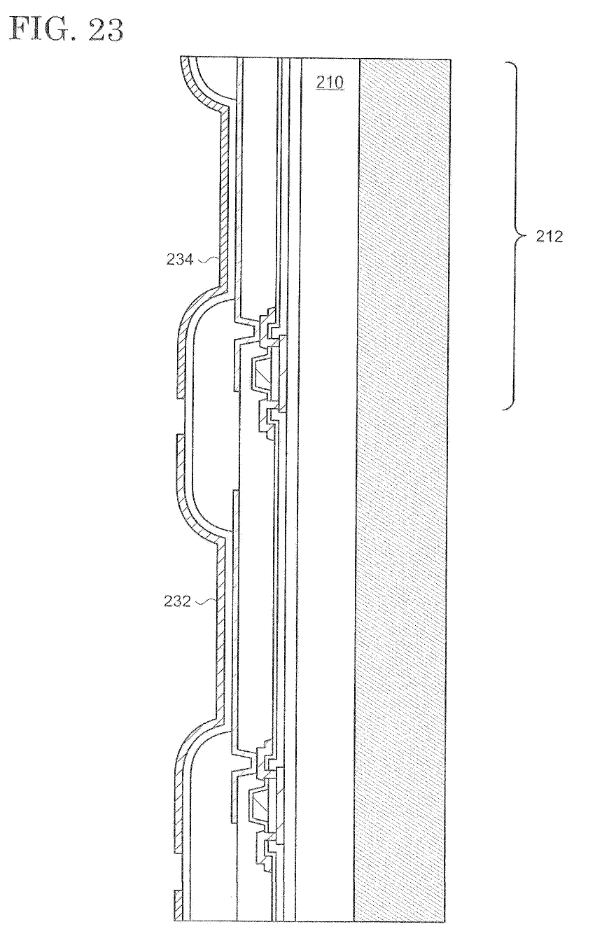

After forming the first emission layer 232, a second emission layer 234 is formed. Specifically, the metal mask 144 having an opening portion 224 in a region where the second emission layer 234 is to be formed is arranged between the substrate 140 and the closed tube 108, and a material forming the second emission layer 234 is evaporatively deposited with the same method as that of the evaporative deposition of the first emission layer 232 (see, FIG. 22). With this process, the first emission layer 232 and the second emission layer 234 which are different between the adjacent pixels 212 are formed (see, FIG. 23). Three kinds of emission layers respectively giving the three primary colors are formed in turn by repeating this procedure, by which a display device capable of full-color display can be manufactured.

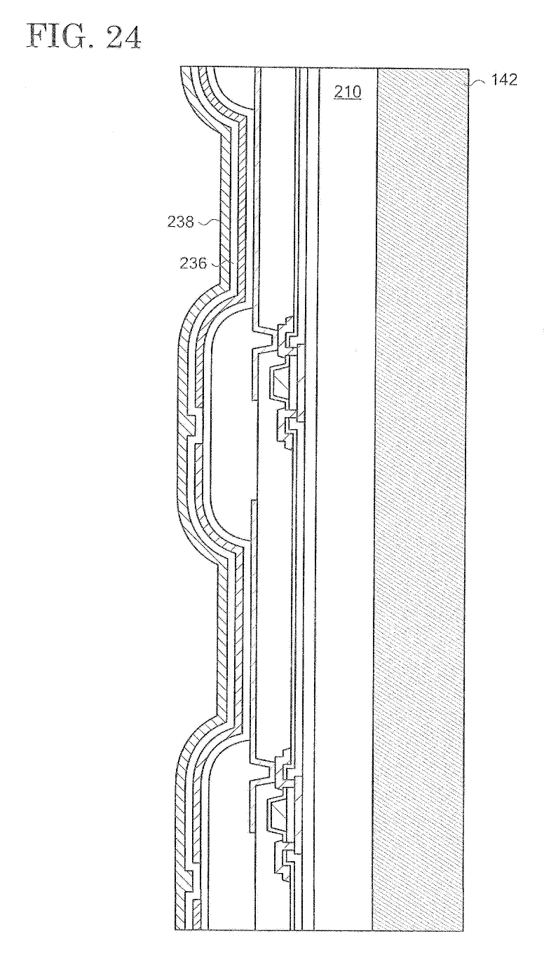

After that, similar to the evaporative deposition of the first carrier-injection/transporting layer 230, a second carrier-injection/transporting layer 236 is formed (FIG. 24). When the pixel electrode 218 is used as an anode, a material to which electrons are readily injected and which has a high electron mobility is used for the second carrier-injection/transporting layer 236. For example, a complex including a typical metal and a nitrogen-including heteroaromatic compound are typical examples. The second carrier-injection/transporting layer 236 may be fabricated by co-evaporating these materials with a compound with an electron-donating property.

Similar to the evaporative deposition of the first carrier-injection/transporting layer 230, an opposing electrode 238 is sequentially formed (FIG. 24). When the pixel electrode 218 is used as an anode, the opposing electrode 238 functions as a cathode. In this case, aluminum, magnesium, silver, or an alloy thereof can be used as a material, for example. Note that a conductive oxide with a transmitting property with respect to visible light, such as indium-tin oxide (ITO) and indium-zinc oxide (IZO), can be used for the opposing electrode 238. In such a case, the opposing electrode 238 may be formed by using a sputtering apparatus and the like instead of the film-forming apparatus 100 of the present embodiment, for example.

The formation of each layer (first carrier-injection/transporting layer 230, first emission layer 232, second emission layer 234, and second carrier-injection/transporting layer 236) may be performed in the same chamber. Alternatively, each layer may be formed in a different chamber by using a different film-forming apparatus 100. Furthermore, when each material is evaporated, the closed tube 108 of each film-forming apparatus 100 may be installed with the sheet-shaped heater 110 in the most appropriate mode.

Through the aforementioned processes, a display device having a light-emitting element in each pixel 212 can be manufactured. In the manufacturing method of a display device described in the present embodiment, the evaporative deposition is performed while the substrate 140 is arranged so that the main surface is perpendicular to a horizontal direction. Hence, an area occupied by the film-forming apparatus 100 can be suppressed, and a display device can be manufactured from a substrate with a large size by using a small size film-forming apparatus 100.

Additionally, as described in the First Embodiment, the film-forming apparatus 100 makes it possible to form a thin film with a uniform thickness over the substrate 140 having a large size. Hence, variation in characteristics of a light-emitting element included in a display device can be reduced, allowing production of a display device capable of providing a high-quality image.

The aforementioned modes described as the embodiments of the present invention can be implemented by appropriately combining with each other as long as no contradiction is caused. Furthermore, any mode which is realized by persons ordinarily skilled in the art through the appropriate addition, deletion, or design change of elements or through the addition, deletion, or condition change of a process is included in the scope of the present invention as long as they possess the concept of the present invention.

In the specification, although the cases of the organic EL display device are exemplified, the embodiments can be applied to any kind of display devices of the flat panel type such as other self-emission type display devices, liquid crystal display devices, and electronic paper type display device having electrophoretic elements and the like. In addition, it is apparent that the size of the display device is not limited, and the embodiment can be applied to display devices having any size from medium to large.

It is properly understood that another effect different from that provided by the modes of the aforementioned embodiments is achieved by the present invention if the effect is obvious from the description in the specification or readily conceived by persons ordinarily skilled in the art.

What is claimed is:

1. A film-forming apparatus comprising:
an evaporation source;
a head connected to the evaporation source and comprising a plurality of opening portions; and
a heater wound around the head, the heater comprising:
a first region at a side of the evaporation source; and
a second region at an opposite side of the first region from the evaporation source,
wherein the heater located in the first region is arranged in a first arrangement state, and
the heater located in the second region is arranged in a second arrangement state different from the first arrangement state.

2. The film-forming apparatus according to claim 1,
wherein the heater is arranged so as to pass between the plurality of opening portions.

3. The film-forming apparatus according to claim 1,
wherein the heater has a portion in which the heater is wound a plurality of times in both the first region and the second region, and
wherein a first winding number of the heater in the first region is different from a second winding number of the heater in the second region.

4. The film-forming apparatus according to claim 3,
wherein the second winding number is larger than the first winding number.

5. The film-forming apparatus according to claim 1,
wherein a first width of the heater in the first region is different from a second width of the heater in the second region.

6. The film-forming apparatus according to claim 5,
wherein the second width is larger than the first width.

7. The film-forming apparatus according to claim 1,
wherein the heater includes an electrical heating wire,
the electrical heating wire bends a plurality of times and has a plurality of liner parts extending in a first direction which is a longitudinal direction of the head,
the heater has a first portion in the first region and a second portion in the second region,
a first number of liner parts among the liner parts are located in the first portion and arranged in a second direction intersecting the first direction,
a second number of liner parts among the liner parts are located in the second portion and arranged in the second direction, and
the first number is different from the second number.

8. The film-forming apparatus according to claim 7,
wherein the second number is larger than the first number.

9. The film-forming apparatus according to claim 1,
wherein the heater has a sheet shape and is attachable to and detachable from the head.

10. A film-forming apparatus comprising:
an evaporation source;
a closed tube covering the evaporation source, having an open end connected to the evaporation source, and comprising a plurality of opening portions; and
a heater wound around the closed tube,
wherein the heater is arranged in a first arrangement state at a side of the open end, and is arranged in a second arrangement state at an opposite side of the side from the open end, and
the first arrangement state is different from the second arrangement state.

11. The film-forming apparatus according to claim 10,
wherein the heater is wound a plurality of times at a same position on the closed tube, and
wherein a winding number of the heater increases with increasing a distance from the open end to the heater.

12. The film-forming apparatus according to claim 10,
wherein a width of the heater increases with increasing a distance from the open end to the heater

13. The film-forming apparatus according to claim 10, further comprising a substrate holder which holds a substrate so that a main surface of the substrate is arranged perpendicularly to a horizontal direction,
wherein the plurality of the opening portions face the substrate holder.

14. A film-forming method including:
a step of heating a material at an evaporation source and vaporizing the material;
a step of supplying vapor of the material into a head connected to the evaporation source and comprising a plurality of opening portions;
a step of ejecting the vapor from the head through the plurality of opening portions; and
a step of heating the head with a heater wound around the head during the heating of the material,
wherein the heater comprises:
a first region at a side of the evaporation source; and
a second region at an opposite side of the first region from the evaporation source,
the heater located in the first region is arranged in a first arrangement state, and
the heater located in the second region is arranged in a second arrangement state different from the first arrangement state.

15. The film-forming method according to claim 14,
wherein the head is arranged so that a longitudinal direction of the head is perpendicular to a horizontal direction.

16. The film-forming method according to claim 15,
wherein a substrate is arranged so that a main surface of the substrate is perpendicular to a horizontal direction, and the vapor is ejected from the head while the plurality of opening portions facing the main surface.

17. The film-forming method according to claim 14,
wherein the step of heating the head with the heater solves a temperature gradient of the head.

18. The film-forming method according to claim 14,
wherein the heater has a portion in which the heater is wound a plurality of times in both the first region and the second region, and
wherein a first winding number of the heater in the first region is different from a second winding number of the heater in the second region.

19. The film-forming method according to claim 14,
wherein a first width of the heater in the first region is different from a second width of the heater in the second region.

20. The film-forming method according to claim 14,
wherein:
the heater includes an electrical heating wire;
the electrical heating wire extends in a first direction which is a longitudinal direction of the head and has a plurality of portions arranged in a second direction intersecting the first direction; and
a first number of the portions of the electrical heating wire arranged in the second direction in the first region and a second number of the portions of the electrical heating wire arranged in the second direction in the second region are different from each other, wherein the heater includes an electrical heating wire,
the electrical heating wire bends a plurality of times and has a plurality of liner parts extending in a first direction which is a longitudinal direction of the head,
the heater has a first portion in the first region and a second portion in the second region,
a first number of liner parts among the liner parts are located in the first portion and arranged in a second direction intersecting the first direction,
a second number of liner parts among the liner parts are located in the second portion and arranged in the second direction, and
the first number is different from the second number.
